(19) United States
(12) Patent Application Publication
(10) Pub. No.: US 2013/0009294 A1
(43) Pub. Date: Jan. 10, 2013

(54) MULTI-CHIP PACKAGE HAVING LEADERFRAME-TYPE CONTACT FINGERS

(76) Inventor: Hui-Chang CHEN, Hsinchu (TW)

(21) Appl. No.: 13/176,303

(22) Filed: Jul. 5, 2011

(51) Int. Cl. H01L 23/495

(52) U.S. Cl. 257/670; 257/676; 257/E23.031

(57) ABSTRACT

Disclosed is a multi-chip package having leadframe-type contact fingers, primarily comprising a leadframe, a non-conductive tape, a first chip and a second chip disposed on the first chip. The leadframe includes a die paddle on which the first chip is disposed and a plurality of first contact fingers, moreover, at least a second contact finger is integrally extended from the die paddle and is located among the first contact fingers so that the first and second contact fingers are arranged in a row. The non-conductive tape is attached onto the first and second contact fingers conforming to the arranging row of the first contact fingers so that the second contact finger is mechanically fastened with the first contact fingers. An encapsulant encapsulates the first chip, the second chip and the non-conductive tape with a plated metal layer formed on the bottom surfaces of the first and second contact fingers and exposed from the encapsulant. Accordingly, delamination of the conventional substrate or a die paddle can be avoided and the amount of tie bars used can be decreased.

### FIELD OF THE INVENTION

The present invention relates to a multi-chip package for semiconductor devices, and more specifically to a multi-chip package having leadframe-type contact fingers.

### BACKGROUND OF THE INVENTION

Multi-chip package is a new packaging technology trend where a plurality of chips are stacked and assembled in one package to achieve better functions with larger capacity such as memory card or eMMC (embedded Multi Media Card). The chip carrier of memory card implemented in the existing Multi-Chip Package (MCP) is a substrate made of printed circuit boards with glass fiber cores or flex circuit boards where an encapsulant formed by molding is disposed on the substrate to encapsulate the chips on the substrate. Besides higher packaging cost, the bottom surface of the substrate which is not encapsulated and protected by the encapsulant is vulnerable for worn damage, substrate delamination, package warpage, and poor moisture resistance. Therefore, a leadframe is proposed to replace the substrate in MCP technology.

In U.S. Pat. No. 7,795,715 B2 entitled “leadframe based flash memory cards”, Takiar et al. disclosed a multi-chip package of memory card implemented a leadframe as a chip carrier where the leadframe includes a die paddle to carry chips, electric leads, and contact pads. However, before singulation contact pads and die paddle are individually and directly connected to a metal frame of the leadframe outside the encapsulant by a plurality of tie bars which are not firmly held during the packaging processes. Once the contact pads or die paddle sway or shift, encapsulant bleeding or lead shifting would be encountered. Furthermore, as the portions of contact pads and die paddle connected to the leadframe which are extended to the inserting side of the memory card, ESD is easily occurred leading to ESD damage and contact pads and die paddle are vulnerable for peeling.

### SUMMARY OF THE INVENTION

The main purpose of the present invention is to provide a multi-chip package with leadframe-type contact fingers to eliminate substrates for lower packaging cost and to avoid encapsulant bleeding of contact fingers and shifting of the die paddle of a leadframe.

The second purpose of the present invention is to provide a multi-chip package with leadframe-type contact fingers to effectively resolve issues of swaying and shifting of contact fingers formed from a leadframe.

According to the present invention, a multi-chip package with leadframe-type contact fingers is revealed in the present invention. The multi-chip package comprises a leadframe, a non-conductive tape, a first chip, a second chip, a plurality of bonding wires, an encapsulant, and a plated metal layer. The leadframe includes a die paddle and a plurality of first contact fingers with at least a second contact finger integrally extended from one side of the die paddle where the second contact finger is located among the first contact fingers arranged in a row. The non-conductive tape is attached onto the first contact fingers and the second contact finger conforming to the arranging row of the first contact fingers so that the second contact finger is mechanically fastened with the first contact fingers. The first chip is disposed on the die paddle. The second chip is disposed on the first chip. A plurality of bonding pads of the first chip are electrically connected to the first contact fingers and the second contact finger by the bonding wires. The encapsulant encapsulates the die paddle, the first chip, the second chip, and the non-conductive tape and also firmly holds and joins the first contact fingers and the second contact finger together. The plated metal layer is formed on the bottom surfaces of the first contact fingers and the second contact finger and is exposed from the encapsulant.

The multi-chip package with leadframe-type contact fingers according to the present invention has the following advantages and effects:
1. Through two specific structures of contact fingers along with the attachment of the non-contacting tape as a technical mean, the contact fingers can effectively be integrated on the leadframe to firmly hold the contact fingers before molding, to eliminate the substrate for lower packaging cost, and to avoid encapsulant bleeding of contact pads and lead shifting of a leadframe.
2. Through two specific structures of contact fingers along with the attachment of the non-contacting tape as a technical mean, issues of swaying and shifting of contact pads formed by a leadframe can effectively be resolved.
3. Through multiple holding mechanism to firmly hold contact fingers of a leadframe as a technical mean, the tie bars of a leadframe do not extend to the inserting side of the encapsulant and the amount of tie bars implemented can be reduced to achieve better moisture resistance and ESD protection.
4. Through the difference between the width of the non-conductive tape and the length of contact fingers as a technical mean, a plurality of wire-bonding areas on the contact fingers are reserved for bonding a plurality of bonding wires on the contact fingers and the non-conductive tape can be fully encapsulated by the encapsulant without affecting the appearance of the products.
5. Through thickness differences between the contact fingers and the die paddle of the leadframe as a technical mean, the encapsulant is able to fully encapsulate the bottom surface of the die paddle except the bottom surfaces of the contact fingers which is specially suitable for low cost solutions of memory cards.

### DESCRIPTION OF THE DRAWINGS

FIG. 1 is a cross-sectional view of a multi-chip package with leadframe-type contact fingers according to the preferred embodiment of the present invention.

FIG. 2 is a top view of the multi-chip package by seeing through its encapsulant according to the preferred embodiment of the present invention.

FIGS. 3A to 3G are component top views of the multi-chip package illustrating its fabrication processing steps according to the preferred embodiment of the present invention.

FIG. 4 is a top view of a leadframe illustrating the step of “providing a leadframe” as shown in FIG. 3A where a plurality of packaging units are formed on a leadframe.

FIG. 5 is a top view of a wafer illustrating a first chip picked up from the wafer before the processing step of “disposing a first chip” as shown in FIG. 3B.

FIG. 6 is a top view of the leadframe of FIG. 4 illustrating continuous encapsulation on the plurality of packaging units by an encapsulant after the processing step of “forming an encapsulant” as shown in FIG. 3F.

FIG. 7 is a bottom view of the encapsulant after the processing step of “singulating the encapsulated leadframe” as shown in FIG. 3G.

FIG. 8 is a bottom view of the multi-chip package illustrating a plated metal layer formed on the bottom surfaces of the contact fingers.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

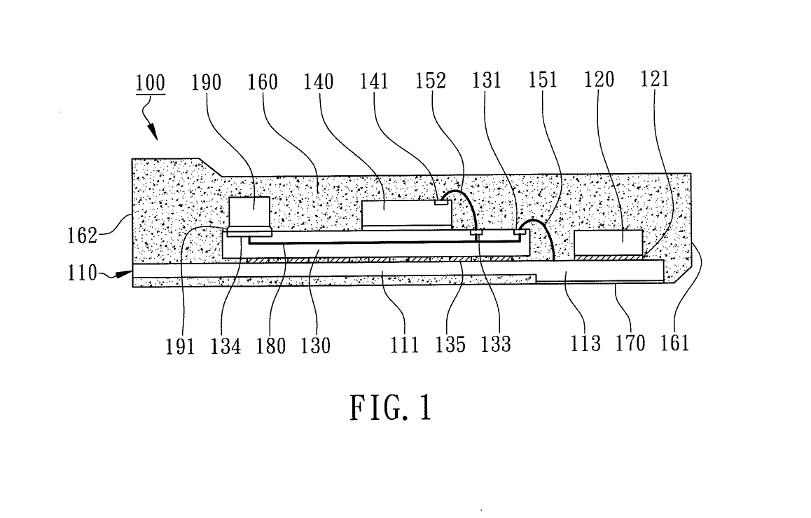

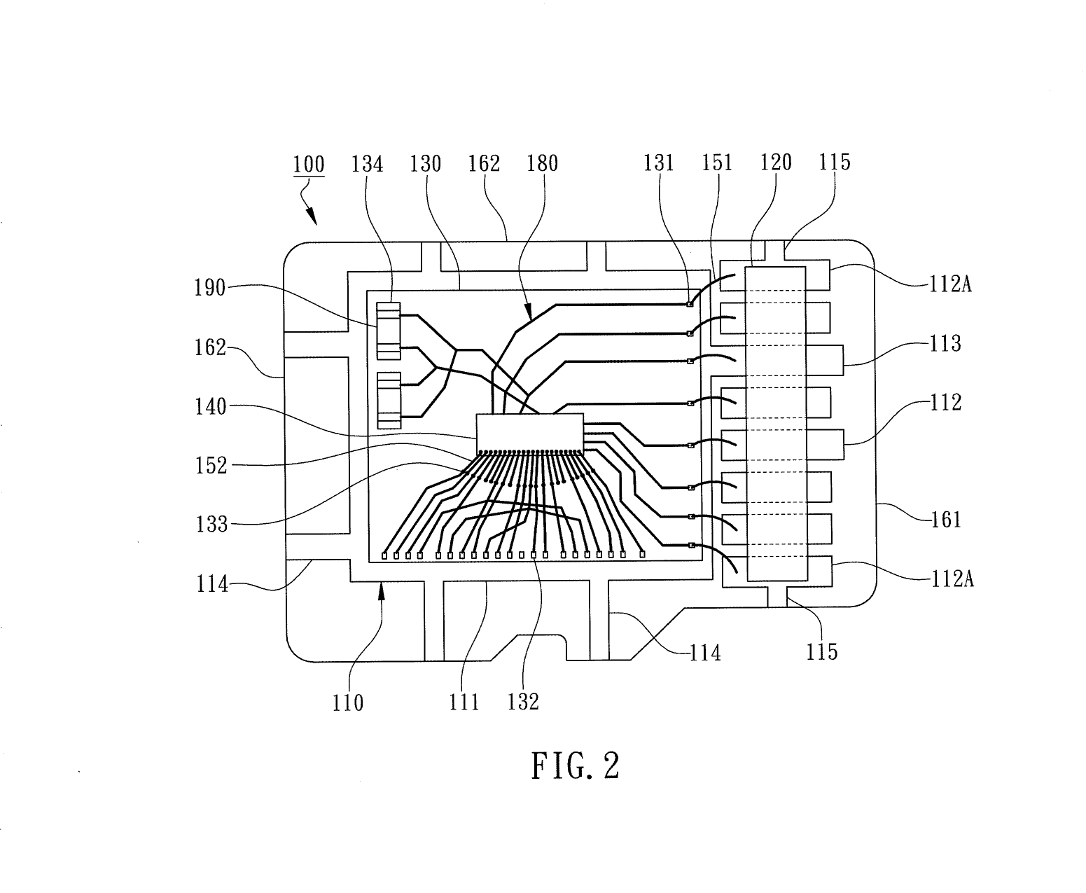

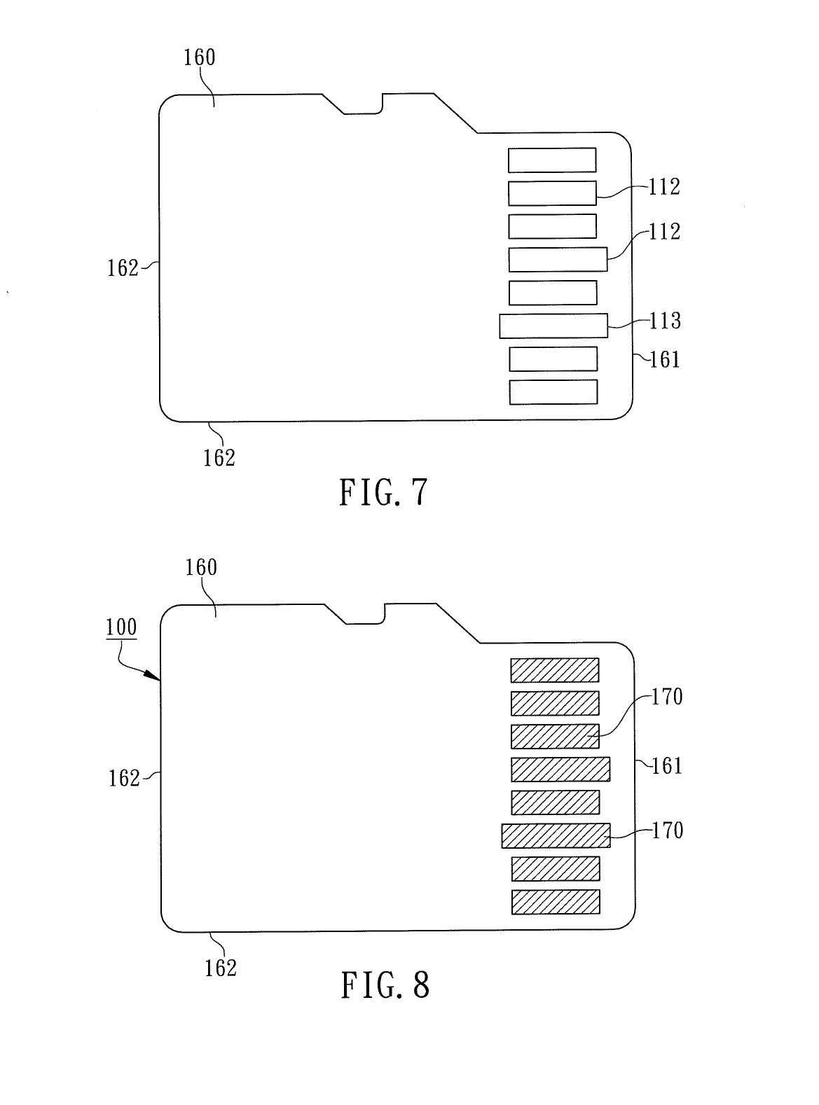

According to the preferred embodiment of the present invention, a multi-chip package 100 with leadframe-type contact fingers is illustrated in FIG. 1 for a cross-section, in FIG. 2 for a top view seeing through the encapsulant, and in FIG. 8 for a bottom view. The multi-chip package 100 comprises a leadframe 110, a non-conductive tape 120, a first chip 130, a second chip 140, a plurality of first bonding wires 151, an encapsulant 160, and a plated metal layer 170.

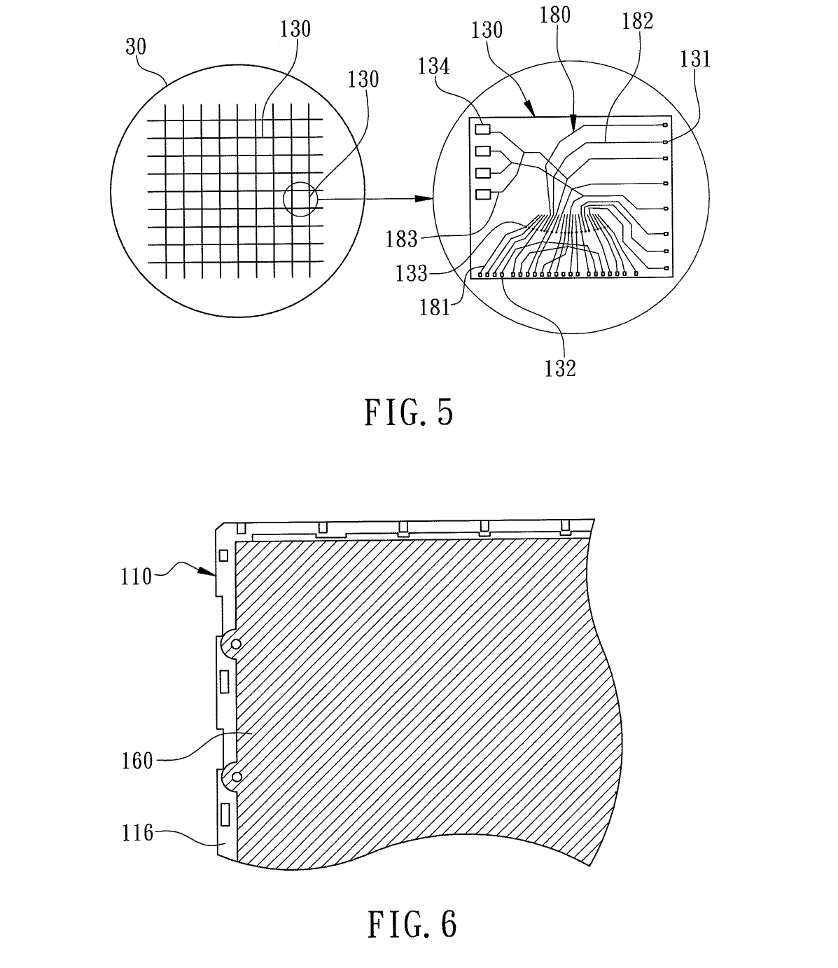

The leadframe 110 is a metal frame where the metal can be Ni—Fe alloy or Cu alloy served as a chip carrier having gaps for filling the encapsulanat which is quite different from the non-conductive core and a non-encapsulated bottom surface of a substrate. As shown in FIG. 1 and FIG. 2, the leadframe 100 includes a die paddle 111 and a plurality of first contact fingers 112, which means that the die paddle 111 and the first contact fingers 112 are made of the same material and on the same leadframe. In a final product, the first contact fingers 112 are individually separated. Each first contact finger 112 has a width and a length where the length is greater than the width. And the first contact fingers 112 are arranged in a row where the arranging row of the first contact fingers 112 is perpendicular to the lengths of the first contact fingers 112. Furthermore, one side of the die paddle 111 is further integrally extended and connected to at least a second contact finger 113 where the second contact finger 113 is located among the first contact fingers 112 arranged in the row. The width of the second contact finger 113 is the same as the one of the first contact fingers 112 but with different lengths. The length of the second contact finger 113, for example, can be slightly longer than the one of the first contact fingers 112 for ground/power connection of a memory card as shown in FIG. 7. Accordingly, the second contact finger 113 can be electrically connected as power or ground pins where the first contact fingers 112 are majorly configured for signal transmission. In the present embodiment, the first contact fingers 112 and the second contact finger 113 are the golden fingers of a memory card for external electrical connections.

As shown in FIG. 2, the non-conductive tape 120 is attached onto the first contact fingers 112 and the second contact finger 113 conforming to the arranging row of the first contact fingers 112 so that the second contact finger 113 is mechanically fastened with the first contact fingers 112. In the present embodiment, the non-conductive tape 120 is in strip form with the disposed orientation perpendicular to the extended direction of the second contact finger 113 so that the non-conductive tape 120 can adhere to the first contact fingers 112 and the second contact finger 113 in a shorter distance. As shown in FIG. 1, an adhesive layer 121 is formed on the bottom of the non-conductive tape 120 to adhere to the second contact finger 113 and the first contact fingers 112 simultaneously. Therefore, before the molding processing step of MCP packaging processes, the second contact finger 113 is integrally connected to the die paddle 111 and can be firmly held with the first contact fingers 112 by the non-conductive tape 120 where constant gaps between the first contact fingers 112 and the second contact finger 113 can be well kept through the adhesion of the non-conductive tape 120.

The first chip 130 is disposed on the die paddle 111, for example, an die-attaching adhesive 135 adheres the back surface of the first chip 130 to the top surface of the die paddle 111. In the present embodiment, the die-attaching adhesive 135 consists of a plurality of the adhesive tapes in a parallel strip form attached to the back surface of the first chip 130 so that the back surface of the first chip 130 and one or more gaps between the adhesive tapes also can be encapsulated by the encapsulant 160. Furthermore, the second chip 140 is disposed on the first chip 130. Preferably, the dimension of the first chip 130 can be larger than the one of the second chip 140 to be a mother chip for carrying the second chip 140. In the present embodiment, the first chip 130 can be a memory chip and the second chip can be a controller chip. To be more specific, a redistribution circuitry layer (RDL) 180 is disposed on the active surface of the first chip 130 to electrically connect the second chip 140 to the first contact fingers 112 and the second contact finger 113. The RDL 180 is a circuitry formed by wafer-level packaging through semiconductor fabrication processes so that the thickness of the stacked chips does not increase. Moreover, the active surface of the first chip 130 is the surface where semiconductor circuitry is fabricated. In the present embodiment, the active surface is facing upward and away from the die paddle 111.

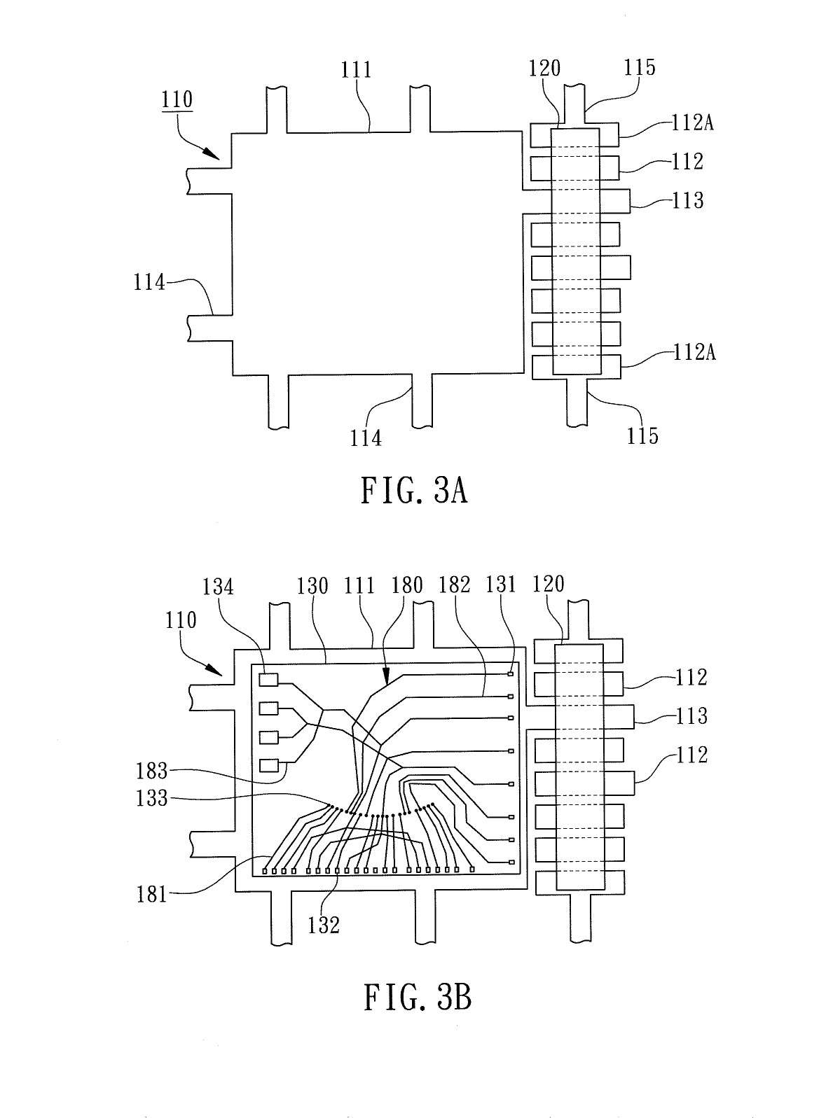

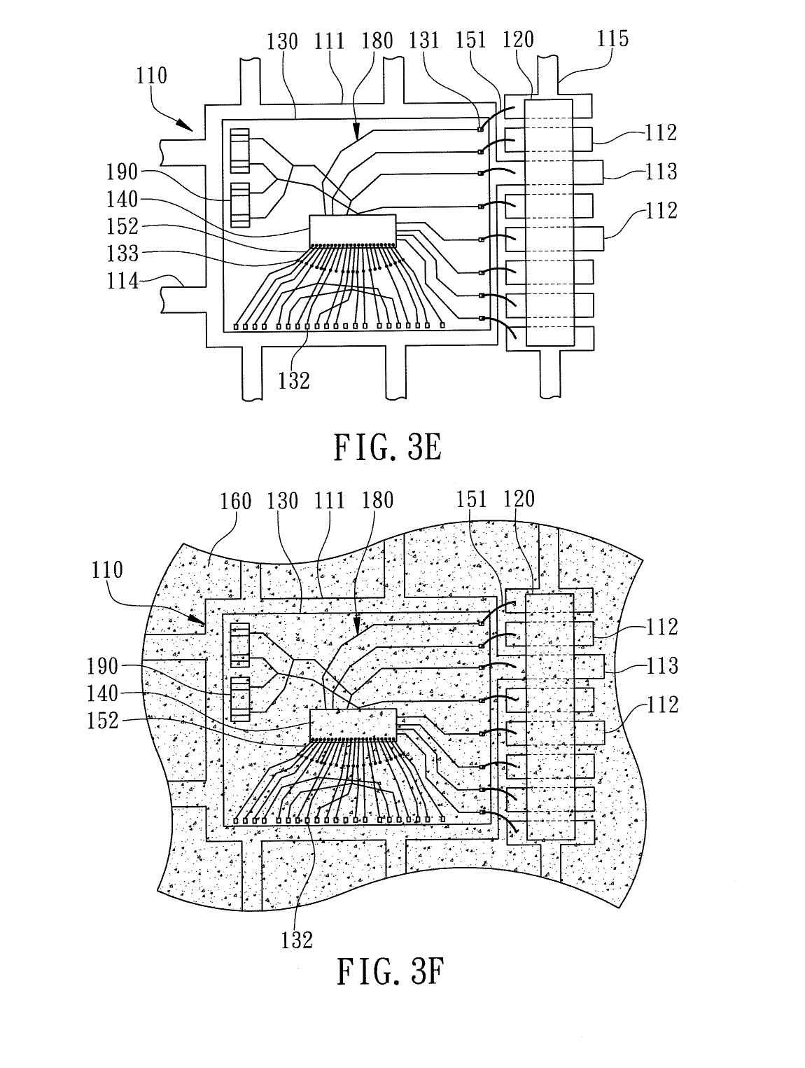

A plurality of bonding pads 131 of the first chip 130 are electrically connected to the first contact fingers 112 and the second contact finger 113 by the first bonding wires 151 where the bonding pads 131 are redistributed bonding pads of the RDL 180 adjacent to the first contact fingers 112 and the second contact finger 113. In a more specific embodiment, the first chip 130 further has a plurality original pads 132 on its active surface and the RDL 180 includes a plurality of transferring bonding pads 133, at least a first circuitry 181 and a second circuitry 182 where the first circuitry 181 electrically connects the original bonding pads 132 to the transferring bonding pads 133 and the second circuitry 182 electrically connects the transferring pads 133 to the redistributed bonding pads 131 to as shown in FIG. 3B and FIG. 5. The RDL 180 is to redistribute all the terminals of the chips such as signal, power, and ground to the redistributed bonding pads 131 at the desired wire-bonded locations. Therefore, the first chip 130 can be electrically connected to the first contact fingers 112 and the second contact finger 113 by wire bonding without wire sweeping issues. The second chip 140 is electrically connected to the RDL 180 by either wire bonding or by flip chip bonding. In the present embodiment, the plurality of bonding pads 141 of the second chip 140 are electrically connected to the transferring pads 133 by a plurality of second bonding wires 152 where the transferring pads 133 are electrically connected to the circuitry of the RDL 180. Moreover, in order to perform wire bonding processes on the first contact fingers 112 and the second contact finger 113, preferably, the width of the non-conductive tape 120 can be smaller than each of the finger lengths of the first contact fingers 112 and the second contact finger 113 so that the top surfaces of the first contact fingers 112 and the second contact finger 113 include a plurality of wire-bonding areas reserved for wire bonding connection of the first bonding wires 151. These wire-bonding areas on the first contact fingers 112 and the second contact finger 113 are facing toward the die paddle 111 without covering by the non-conductive tape 120 as shown in FIG. 2. Furthermore, the non-conductive tape 120 and the first chip 130 are disposed on the same horizontal plane of the leadframe 110 for simultaneous encapsulation.

The encapsulant 160 encapsulates the die paddle 111, the first chip 130, the second chip 140, and the non-conductive tape 120 and also firmly holds and joins the first contact fingers 112 and the second contact finger 113 together. Preferably, the thickness of the first contact fingers 112 and the second contact finger 113 can be thicker than the one of the die paddle 111 in a manner that the encapsulant 160 can encapsulate the bottom surface of the die paddle 111, i.e., a surface opposing to the top surface of the die paddle 111 and far away from the first chip 130. The encapsulant 160 is formed by transfer molding where the encapsulant 160 can be epoxy molding compound (EMC).

In the present embodiment, the encapsulant 160 has the appearance of a memory card as shown in FIG. 1, FIG. 2, FIG. 7 and FIG. 8 such as the appearance of a micro SD card. In a more specific structure, the encapsulant 160 has an inserting side 161 which is a side of the encapsulant 160 adjacent to the first contact finger 112 and the second contact finger 113, i.e., the side to insert the memory card to a socket. The rest of the sides of the encapsulant 160 are non-inserting sides 162. Preferably, the leadframe 110 further includes a plurality of first tie bars 114 and a plurality of second tie bars 115 where the first tie bars 114 mechanically connect the die paddle 111 to the non-inserting sides 162 of the encapsulant 160 and the second tie bars 115 mechanically connect some of the first contact fingers 112A located at two side of the arranging row to the non-inserting sides 162 of the encapsulant 160. Since the first contact fingers 112 and the second contact finger 113 are adhered by the non-conductive tape 120 in series, the first contact fingers 112 and the second contact finger 113 are firmly held in place so that the second tie bars 113 are not necessary to individually connect the first contact fingers 112 to the non-inserting sides 162 and there is no cut ends of the tie bars formed on the inserting side 161 to avoid damages caused by ESD and to reduce the amount of implemented tie bars. Furthermore, the plated metal layer 170 are formed on the bottom surfaces of the first contact fingers 112 and the second contact finger 113 and are exposed from the encapsulant 160 to prevent oxidation of the first contact fingers 112 and the second contact finger 113 to enhance external electrical conductivity. In the present embodiment, the plated metal layer 180 is a Ni—Au layer formed by barrel plating technique.

Furthermore, the multi-chip package 100 further comprises at least a passive component 190 disposed on the first chip 130 and electrically connected to the RDL layer 180 where the passive component 190 is also encapsulated by the encapsulant 160. In the present embodiment, the RDL layer 180 further includes a plurality of solder pads 134 which are electrically connected to parts of the second circuitry 182 through a third circuitry 183 of the RDL 180 as shown in FIG. 3B and FIG. 5. The electrodes of the passive component 190 are soldered to the solder pads 134 by solder paste 191 to dispose the passive component 190 on the first chip 130.

The manufacture method of the multi-chip package with leadframe-type contact fingers is further described in detail from FIG. 3A to FIG. 3G for component top views during each packaging processing step.

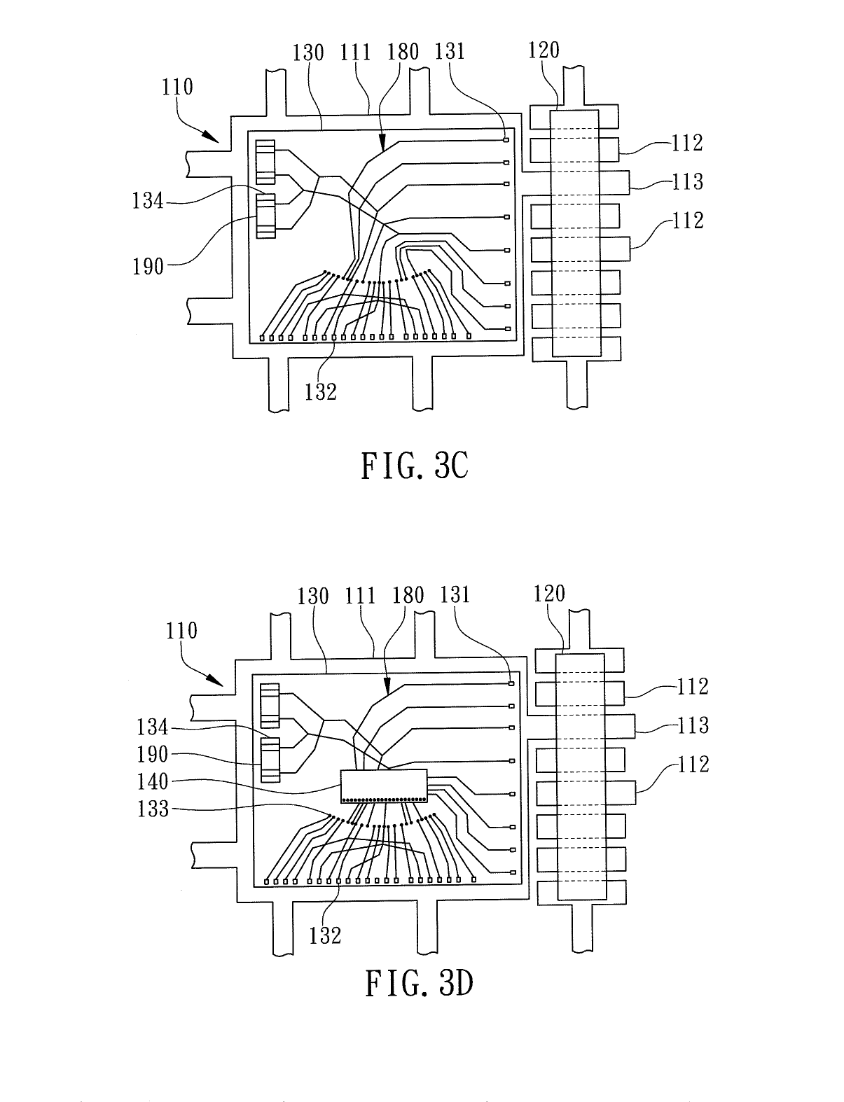

As shown in FIG. 3A and FIG. 4, proceed the step of “providing a leadframe” where the leadframe 110 includes a plurality of packaging units 110A each corresponding to one multi-chip package 100 located within a metal frame 116. Formed in each packaging unit 110A are the die paddle 111, the first contact fingers 112, and the second contact finger 113. One side of the die paddle 111 is further integrally extended and connected with the second contact finger 113 where the first contact fingers 112 and the second contact finger 113 are firmly held by the non-conductive tape 120. The die paddle 111 is mechanically connected to the metal frame 116 or to the adjacent packaging unit 110A by the first tie bars 114. Some of the first contact fingers 112A located at both sides of the arranging row of the first contact fingers 112 are mechanically connected to the metal frame 116 or to the adjacent packaging units 110A by the second tie bars 115. Therefore, the separated first contact fingers 112 can be firmly held before molding processes.

Then, proceed the step of “disposing a first chip”. As shown in FIG. 3B, the first chip 130 is disposed on the die paddle 111. As shown in FIG. 5, the first chip 130 is picked up from a wafer 30 where the first chip 130 including the RDL 180 is fabricated on a wafer 30 before singulated into individual chips. When the first chip 130 is disposed on the die paddle 111, the redistributed bonding pads 131 are adjacent to the first contact fingers 112 and the second contact finger 113 to shorten bonding wire lengths. In a preferred embodiment, as shown in FIG. 3C, at least a passive component 190 is disposed on the first chip 130 where the electrodes of the passive component 190 are aligned and soldered to the solder pads 134.

Then, proceed the step of “disposing a second chip”. As shown in FIG. 3D, the second chip 140 is disposed on the first chip 130. When the second chip 140 is electrically connected to the RDL 180 by wire bonding processes, the second chip 140 does not cover the transferring pads 133. Then, proceed the step of “forming the bonding wires” as shown in FIG. 3E, the first bonding wires 151 and the second bonding wires 152 are formed by wire bonding processes where the first bonding wires 151 electrically connect the redistributed bonding pads 131 to the first contact fingers 112 and to the second contact finger 113 and the second bonding wires 152 electrically connect the bonding pads of the second chip 140 to the transferring pads 133. Therefore, the second chip 140 is electrically connected to the first chip 130 as well as to the first contact fingers 112 and the second contact finger 113.

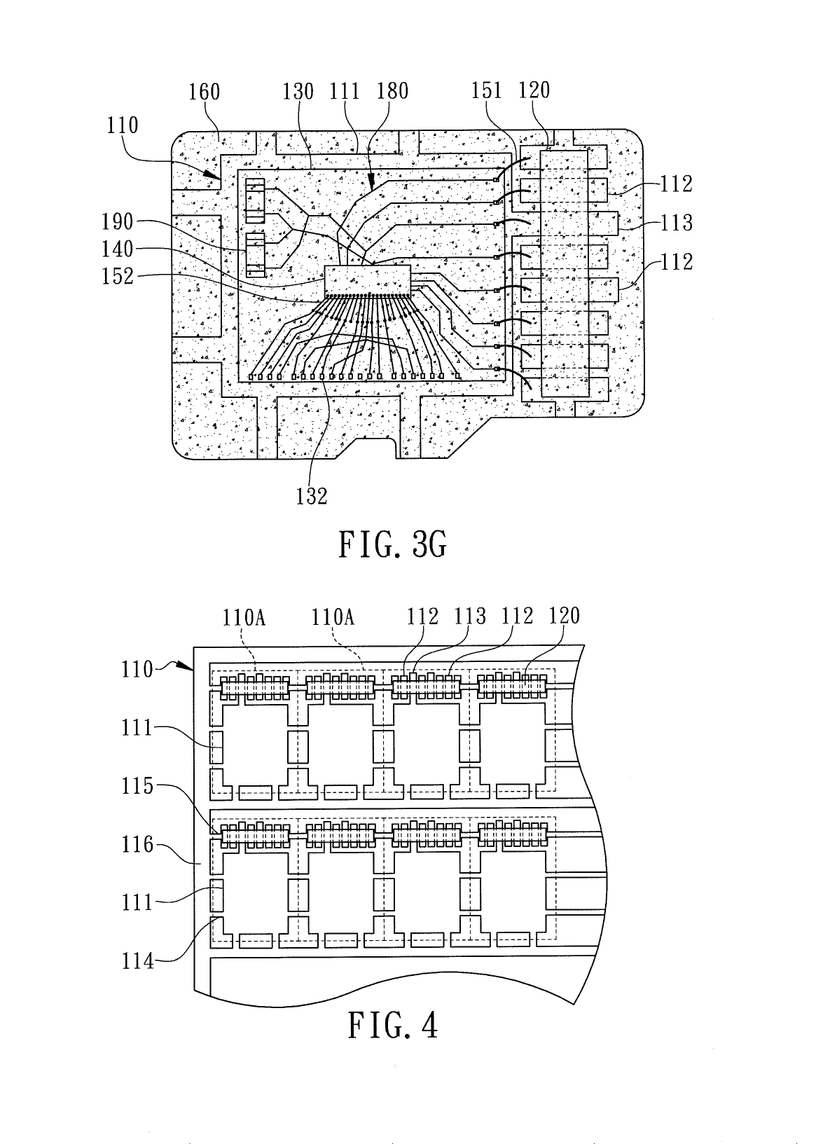

Then, proceed the step of “encapsulating”, as shown in FIG. 3F, the encapsulant 160 is formed to encapsulate the first chip 130, the second chip 140, the passive component 190, the first bonding wires 151, the second bonding wires 152, and the non-conductive tape 120 and to mechanically hold and join the first contact fingers 112 and the second contact finger 113 of the leadframe 110. As shown in FIG. 6, the encapsulant 160 is continuously formed on a plurality of packaging units 110A within the metal frame 116 to meet the requirements of mass production.

Then, proceed the step of “singulating the encapsulant”. As shown in FIG. 3F, the encapsulant 160 is singulated into the appearance of a memory card as shown in FIG. 3G. Since all the singulated sidewalls are made of encapsulant 160 during singulation without singulating the sidewalls as a conventional substrate but only singulating the first tie bars 114 and the second tie bars 115, therefore, more complicated shapes can be singulated. The singulating step may further includes a substep of shaping and polishing to achieve smoother surfaces without burrs and cost reduction to avoid peeling or delamination of a conventional substrate. Preferably, the thickness of the first tie bars 114 and the second tie bars 115 is not larger than the thickness of the die paddle 111 and is thinner than the thickness of the first contact fingers 112 and the second contact finger 113 so that the singulated cross-sections of the first tie bars 114 and the second tie bars 115 would not press to the top and bottom edges of the singulated sidewalls of the encapsulant 160, i.e., the peripheries of the singulated cross-sections of the first tie bars 114 and the second tie bars 115 are still encapsulated by the encapsulant 160 to reduce the burr and to avoid the shifting of the first tie bars 114 and the second tie bars 115. As shown in FIG. 7, after singulation processes, only the bottom surfaces of the first contact fingers 112 and the second contact finger 113 are exposed from the bottom surface of the encapsulant 160 where the bottom surface of the die paddle 111 and the bottom surfaces of the first tie bars 114 and the second tie bars 115 are still encapsulated by the encapsulant 160. Finally, as shown in FIG. 8, the exposed bottom surfaces of the first contact fingers 112 and the second contact finger 113 are barrel plated with the plated metal layer 170 to finish the fabrication of the multi-chip package 100.

Therefore, the cost of the multi-chip package with leadframe-type contact fingers according to the present invention can be reduced since the substrate is eliminated and encapsulant bleeding of contact pads and lead shifting of a leadframe can be avoided to effectively resolve the issues of swaying and shifting of contact pads formed by a leadframe.

Furthermore, the multi-chip package with leadframe-type contact fingers revealed in the present invention not only can be implemented in flash memory cards but also in eMMC by simply changing the position of the contact fingers, the corresponding shapes or the amount of the non-conductive tape, and the corresponding RDL circuitry.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A multi-chip package comprising:
a leadframe including a die paddle and a plurality of first contact fingers with at least a second contact finger integrally extended from one side of the die paddle, wherein the second contact finger is located among the first contact fingers arranged in a row;
a non-conductive tape attached onto the first contact fingers and the second contact finger conforming to the arranging row of the first contact fingers so that the second contact finger is mechanically fastened with the first contact fingers;
a first chip disposed on the die paddle;
a second chip disposed on the first chip;
a plurality of first bonding wires electrically connecting a plurality of bonding pads of the first chip to the first contact fingers and the second contact finger;
an encapsulant encapsulating the die paddle, the first chip, the second chip, and the non-conductive tape and also firmly holding and joining the first contact fingers and the second contact finger together; and
a plated metal layer formed on a plurality of bottom surfaces of the first contact fingers and the second contact finger and exposed from the encapsulant.

2. The multi-chip package as claimed in claim 1, wherein the dimension of the first chip is larger than the one of the second chip.

3. The multi-chip package as claimed in claim 2, wherein the first chip is a memory chip and the second chip is a controller chip.

4. The multi-chip package as claimed in claim 3, wherein the encapsulant has an appearance of a memory card.

5. The multi-chip package as claimed in claim 4, wherein the encapsulant has an inserting side, wherein the leadframe further includes a plurality of first tie bars and a plurality of second tie bars where the first tie bars mechanically connect the die paddle to a plurality of non-inserting sides of the encapsulant, and the second tie bars mechanically connect some of the first contact fingers located at two sides of the arranging row to the non-inserting side of the encapsulant.

6. The multi-chip package as claimed in claim 5, wherein the thickness of the first tie bars and the second tie bars is smaller than the thickness of the first contact fingers and the second contact finger, wherein a bottom surface of the die paddle and a plurality of bottom surfaces of the first tie bars and the second tie bars are encapsulated by the encapsulant.

7. The multi-chip package as claimed in claim 2, wherein a redistribution circuitry layer is disposed on an active surface of the first chip for electrically connecting the second chip to the first contact fingers and the second contact finger.

8. The multi-chip package as claimed in claim 7, wherein the redistribution circuitry layer includes a plurality of solder pads, the multi-chip package further comprising at least a passive component disposed on the first chip by soldering to the solder pads of the redistribution circuitry layer.

9. The multi-chip package as claimed in claim 8, wherein the first chip further has a plurality original pads and the redistribution circuitry layer further includes a plurality of transferring bonding pads, at least a first circuitry and a second circuitry, wherein the first circuitry electrically connects the original bonding pads to the transferring bonding pads and the second circuitry electrically connects the transferring pads to the bonding pads.

10. The multi-chip package as claimed in claim 9, wherein the redistribution circuitry layer further includes a third circuitry electrically connecting the solder pads 134 to parts of the second circuitry.

11. The multi-chip package as claimed in claim 1, wherein the plated metal layer is formed by barrel plating.

12. The multi-chip package as claimed in claim 1, wherein the width of the non-conductive tape is smaller than the length of the first contact fingers and smaller than the length of the second contact finger so that a plurality of top surfaces of the first contact fingers and the second contact finger include a plurality of wire-bonding areas on which the connecting ends of the first bonding wires are formed.

13. The multi-chip package as claimed in claim 1, wherein each of the thicknesses of the first contact fingers and the second contact finger is thicker than the one of the die paddle in a manner that the encapsulant encapsulates a bottom surface of the die paddle.

14. The multi-chip package as claimed in claim 1, wherein the arranging row of the first contact fingers is perpendicular to the lengths of the first contact fingers, wherein the length of the second contact finger is slightly longer than the one of the first contact fingers.

15. The multi-chip package as claimed in claim 1, further comprising an die-attaching adhesive adhering a back surface of the first chip to a top surface of the die paddle, wherein the die-attaching adhesive consists of a plurality of the adhesive tapes in a parallel strip form attached to the back surface of the first chip so that the back surface of the first chip and one or more gaps between the adhesive tapes also are encapsulated by the encapsulant.
